(19) United States
(12) Patent Application Publication
(10) Pub. No.: US 2026/0075939 A1
(43) Pub. Date: Mar. 12, 2026

(54) SYSTEMS AND METHODS FOR POROUS WALL COATINGS

(71) Applicant: IQE plc, St. Mellons, Cardiff (GB)

(72) Inventor: Richard HAMMOND, St. Mellons, Cardiff (GB)

(21) Appl. No.: 19/135,463

(22) PCT Filed: Dec. 6, 2023
(86) PCT No.: PCT/EP2023/084573

§ 371 Date: Jun. 4, 2025

(30) Foreign Application Priority Data
Dec. 12, 2022 (GB) 2218642.3

(51) Int. Cl. H10D 86/01; C23C 16/455; C23C 16/56; C30B 23/02; C30B 25/18; H01L 21/762

(52) U.S. Cl. CPC H10D 86/01; C23C 16/45525; C23C 16/56; C30B 23/025; C30B 25/186; H10P 90/1912; H10W 10/181

(57) ABSTRACT

A layered structure includes a substrate, a porous layer over the substrate, and a coating coupled to porous walls of the porous layer. The porous layer has a higher resistivity than the substrate. Advantageously the coating can improve thermal stability of the porous layer, reduce cracking and flaking during high temperature processing, maintain high resistivity of the porous layer, increase thermal conductivity of the porous layer, and reduce self-heating in a device.

### BACKGROUND

### Field

The present disclosure relates to porous apparatuses, systems, and methods, for example, porous apparatuses, systems, and methods for forming porous wall coatings in a porous layer to improve thermal stability, maintain high resistivity, and increase thermal conductivity of the porous layer.

### Background

Semiconductor-on-insulator (SOI) structures are commonly employed to realize radio frequency (RF) designs where low signal leakage is required. These SOI structures use a buried oxide (BOX) under a top device layer in which RF circuit components, such as transistors and/or passive components, can be fabricated. A handle wafer functioning as a substrate under the BOX can result in signal leakage due to RF fringing fields penetrating into the substrate.

Current incumbent RF-SOI technology utilizes a trap-rich SOI to reduce carrier accumulation due to RF fringing fields and improve harmonic losses. A trap-rich layer (e.g., polysilicon) is formed between the handle wafer and the BOX to minimize parasitic surface conduction effects that can adversely affect RF devices in the top device layer. In addition, to further improve substrate harmonic losses, high-resistivity handle wafers (e.g., greater than 3,000 Ω·cm) are used to reduce the amount of free charge carriers. However, this approach requires costly and/or specialized fabrication techniques.

Porous semiconductors are an alternative to SOI substrates. Porous semiconductors can achieve high-resistivity properties on a standard CMOS silicon wafer, rather than a high-resistivity SOI wafer. Porosification can form a porous region with a particular thickness and porosity in a layer or substrate. For example, electrochemically etching a standard low-resistivity (e.g., 1 Ω·cm) silicon wafer can form a thick (e.g., greater than 10 microns) porous silicon surface layer. The porous etch can deplete free charge carriers within the silicon and increase a resistivity of the porous silicon layer by several orders of magnitude (e.g., from 1 Ω·cm to greater than 5,000 Ω·cm). The high-resistivity and low relative permittivity (e.g., about 2.2) of porous silicon can suppress harmonic losses by several orders of magnitude more than trap-rich SOI.

Further, porous silicon provides an epitaxy platform to regrow a defect-free, single crystal silicon epilayer. Epitaxy refers to crystal growth or material deposition in which new crystalline layers are formed with one or more well-defined orientations. Epitaxy can be used to grow high quality, single crystal semiconductors atop the porous layer. For example, such an epilayer can be used as a device layer for RF circuit components (e.g., an RF CMOS switch).

However, when a thick porous layer undergoes high temperature processing (e.g., greater than 400° C.), cracking and flaking in the porous layer can occur. Further, semiconductor atoms in the porous layer can migrate and reorganize during high temperature processing causing thermal instability in the porous layer. In addition, porous silicon has a low thermal conductivity (e.g., about 0.1-5 W/m·K), which can lead to self-heating in an active device channel and degraded output current.

### SUMMARY

Accordingly, there is a need to utilize porous wall coatings in a porous layer to simultaneously improve thermal stability of the porous layer, reduce cracking and flaking during high temperature processing, maintain high resistivity of the porous layer (e.g., greater than 5,000 Ω·cm), increase thermal conductivity of the porous layer (e.g., greater than about 10 W/m·K), and reduce self-heating in a device.

In some aspects, a layered structure can include a substrate, a porous layer over the substrate, and a coating coupled to porous walls of the porous layer. In some aspects, the porous layer can have a higher resistivity than the substrate. Advantageously the coating can improve thermal stability of the porous layer by reducing atom migration during high temperature processing thereby reducing cracking and flaking of the porous layer. Further advantageously the coating can maintain a high resistivity of the porous layer.

In some aspects, the coating has a thermal conductivity of at least 5 W/m·K. In some aspects, the coating has a thermal conductivity of at least 10 W/m·K. In some aspects, the coating has a thermal conductivity of at least 30 W/m·K. In some aspects, the coating has a thermal conductivity of at least 50 W/m·K. Advantageously a coating having a thermal conductivity of at least 10 W/m·K can improve thermal stability of the porous layer at high temperatures and increase a total thermal conductivity of the porous layer.

In some aspects, the coating has a thermal conductivity of at least 100 W/m·K. In some aspects, the coating has a thermal conductivity of at least 300 W/m·K. In some aspects, the coating has a thermal conductivity of at least 500 W/m·K. Advantageously a coating having a high thermal conductivity can improve thermal stability of the porous layer at high temperatures and increase a total thermal conductivity of the porous layer.

In some aspects, the coating can include germanium (Ge), silicon (Si), silicon carbide (SiC), aluminum nitride (AlN), beryllium oxide (BeO), boron nitride (BN), or carbon (C). In some aspects, the coating can include aluminum nitride (AlN). In some aspects, the coating can include an allotrope of carbon including diamond, graphite, graphene, fullerenes, fullerite, carbon nanotubes, amorphous carbon, nanocarbons, glassy carbon, carbon nanofoam, or a combination thereof. Advantageously a coating including one or more of the above materials can improve thermal stability of the porous layer at high temperatures, maintain a high resistivity of the porous layer, and increase a total thermal conductivity of the porous layer.

In some aspects, the coating is electrically insulating. Advantageously an electrically insulating coating can maintain or increase a high resistivity of the porous layer.

In some aspects, the coating extends continuously along the porous walls from a frontside of the porous layer to a backside of the porous layer. Advantageously a continuous coating can maximize a thermal stability of the porous layer at high temperatures and increase a total thermal conductivity of the porous layer.

In some aspects, the coating increases a total thermal conductivity of the porous layer to at least 10 W/m·K. In some aspects, the coating increases a total thermal conductivity of the porous layer to at least 100 W/m·K. Advantageously a porous layer having a high total thermal conductivity can improve thermal stability of the porous layer at high temperatures and reduce self-heating in a device (e.g., transistor) of the layered structure.

In some aspects, the coating has a thickness less than 5 nm. Advantageously a thin coating can improve thermal stability of the porous layer while maintaining low porosity (i.e., high crystallinity) of the porous layer.

In some aspects, the coating completely covers the porous walls. Advantageously a completely filled porous layer can maximize a thermal stability of the porous layer at high temperatures and maximize a total thermal conductivity of the porous layer.

In some aspects, the porous layer has a thickness of at least 2 μm. In some aspects, the porous layer has a thickness of at least 5 μm. In some aspects, the coating is configured to decrease migration of atoms in the porous layer thereby increasing thermal stability of the porous layer at temperatures greater than about 850° C. Advantageously the coating can increase a thermal stability of a thick porous layer and reduce cracking and flaking of the porous layer during high temperature processing.

In some aspects, the layered structure can further include a device in or on the porous layer. In some aspects, the layered structure can further include a passive device in or on the porous layer. The passive device may be an inductor or a filter. Advantageously the device benefits from the thermal stability of the coated porous layer.

In some aspects, the layered structure can further include an epitaxial layer grown directly over the porous layer. In some aspects, the layered structure can further include a semiconductor device in the epitaxial layer. In some aspects, the coating is configured to maintain the higher resistivity of the porous layer thereby decreasing harmonic losses in the semiconductor device. In some aspects, the coating is configured to increase a total thermal conductivity of the porous layer thereby decreasing self-heating effects in an active device channel of the semiconductor device. In some aspects, the semiconductor device can include a transistor of an RF switch. Advantageously the coating can decrease self-heating effects in an active device channel of the semiconductor device by dissipating the generated heat and increase an output current of the semiconductor device.

In some aspects, a layered structure can include a substrate, a porous layer over the substrate, and a coating coupled to porous walls of the porous layer. In some aspects, the porous layer can have a higher resistivity than the substrate. In some aspects, the coating is electrically insulating and has a thermal conductivity of at least 30 W/m·K. Advantageously an electrically insulating, high thermally conductive coating can improve thermal stability of the porous layer at high temperatures, maintain or increase a high resistivity of the porous layer, and increase a total thermal conductivity of the porous layer.

In some aspects, the coating can include Ge, Si, SiC, AlN, BeO, BN, or C. Advantageously a coating including one or more of the above materials can improve thermal stability of the porous layer at high temperatures, maintain a high resistivity of the porous layer, and increase a total thermal conductivity of the porous layer.

In some aspects, the layered structure can further include an epitaxial layer grown directly over the porous layer. Advantageously the coating can improve properties (e.g., thermal stability, thermal conductivity, resistivity) of the porous layer while maintaining the crystallinity of the porous layer for subsequent epitaxy on the porous layer.

In some aspects, a method can include forming a porous layer over a substrate. In some aspects, the porous layer can have a higher resistivity than the substrate. In some aspects, the method can further include forming a coating coupled to porous walls of the porous layer. Advantageously the method can improve thermal stability of the porous layer by reducing atom migration during high temperature processing thereby reducing cracking and flaking of the porous layer. Further advantageously the method can maintain a high resistivity of the porous layer.

In some aspects, the coating has a thermal conductivity of at least 30 W/m·K. Advantageously a coating having a high thermal conductivity can improve thermal stability of the porous layer at high temperatures and increase a total thermal conductivity of the porous layer.

In some aspects, forming the coating can include depositing the coating on the porous walls by atomic layer deposition (ALD). Advantageously ALD can provide fine control of the thickness of the coating in the porous walls to improve thermal stability of the porous layer while maintaining low porosity (i.e., high crystallinity) of the porous layer.

In some aspects, forming the coating can include forming the coating continuously along the porous walls from a frontside of the porous layer to a backside of the porous layer. Advantageously a continuous coating can maximize a thermal stability of the porous layer at high temperatures and increase a total thermal conductivity of the porous layer.

In some aspects, forming the coating can include completely covering the porous walls. Advantageously a completely filled porous layer can maximize a thermal stability of the porous layer at high temperatures and maximize a total thermal conductivity of the porous layer.

In some aspects, the method can further include exposing the porous walls to an acid solution prior to forming the coating. Advantageously the acid solution can remove any native oxide and/or contaminants in the porous walls prior to forming the coating in the porous walls.

In some aspects, the method can further include exposing the porous layer to an acid solution after forming the coating. Advantageously the acid solution can remove any native oxide and/or contaminants on the porous layer after forming the coating in the porous walls.

In some aspects, the method can further include annealing the porous layer. Advantageously annealing can decrease stress in the porous layer and increase thermal stability (e.g., crystallinity) of the porous layer.

In some aspects, forming the porous layer can include porosifying an upper portion of the substrate. Advantageously porosifying the substrate can reduce cost and improve manufacturing efficiency of the layered structure.

In some aspects, the method can further include polishing or etching a frontside of the porous layer after forming the coating. In some aspects, the polishing can include a chemical mechanical polishing (CMP) process. In some aspects, the etching can include a plasma surface etch. Advantageously, the polishing or etching can remove an upper surface layer (e.g., frontside) and expose the underlying porous structure.

In some aspects, the method can further include forming a device in or on the porous layer. In some aspects, the method can further include forming a passive device in or on the porous layer. The device may be an inductor or a filter. Advantageously the device benefits from the improved thermal stability of the coated porous layer.

In some aspects, the method can further include growing an epitaxial layer directly over the porous layer. In some aspects, the method can further include forming a semiconductor device in the epitaxial layer. In some aspects, the semiconductor device can include a transistor of an RF switch. Advantageously the coating can decrease self-heating effects in an active device channel of the semiconductor device by dissipating the generated heat and increase an output current of the semiconductor device.

In some aspects, the method can further include exposing the porous layer to an acid solution after forming the coating and prior to growing the epitaxial layer. Advantageously the acid solution can remove any native oxide and/or contaminants on the porous layer after forming the coating in the porous walls.

In some aspects, the method can further include annealing the porous layer prior to growing the epitaxial layer. Advantageously annealing can decrease stress in the porous layer and increase thermal stability (e.g., crystallinity) of the porous layer prior to growth of the epitaxial layer over the porous layer.

In some aspects, the method can further include polishing or etching a frontside of the porous layer after forming the coating and prior to growing the epitaxial layer. In some aspects, the polishing can include a CMP process. In some aspects, the etching can include a plasma surface etch. Advantageously, the polishing or etching can remove an upper surface layer (e.g., frontside) and expose the underlying porous structure prior to subsequent epitaxial growth to improve the quality of the grown epitaxial layer over the porous layer.

Implementations of any of the techniques described above can include a system, a method, a process, a device, and/or an apparatus. The details of one or more implementations are set forth in the accompanying drawings and the description below. Other features will be apparent from the description and drawings, and from the claims.

Further features and exemplary aspects of the aspects, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the aspects and, together with the description, further serve to explain the principles of the aspects and to enable a person skilled in the relevant art(s) to make and use the aspects.

FIG. 1 is a schematic cross-sectional illustration of a previously known trap-rich SOI layered structure.

FIG. 2 is a schematic cross-sectional illustration of a porosification system, according to an exemplary aspect.

FIG. 3A is a schematic cross-sectional illustration of a porous layered structure, according to an exemplary aspect.

FIG. 3B is a schematic cross-sectional illustration of a porous layered structure, according to an exemplary aspect.

FIG. 4 is a schematic circuit diagram of a transceiver including an RF switch employing stacked transistors, according to an exemplary aspect.

FIG. 5 is a schematic cross-sectional illustration of an uncoated porous layered structure prior to high temperature processing, according to an exemplary aspect.

FIG. 6 is a schematic cross-sectional illustration of the uncoated porous layered structure shown in FIG. 5 after high temperature processing, according to an exemplary aspect.

FIG. 7 is a schematic cross-sectional illustration of a layered structure with limited self-heating, according to an exemplary aspect.

FIG. 8 is a plot of device output current as a function of applied voltage for the layered structure shown in FIG. 7, according to an exemplary aspect.

FIG. 9 is a schematic cross-sectional illustration of the porous layered structure shown in FIG. 3A with self-heating, according to an exemplary aspect.

FIG. 10 is a plot of device output current as a function of applied voltage for the porous layered structure shown in FIG. 9, according to an exemplary aspect.

FIG. 11 is a schematic magnified cross-sectional illustration of the porous layer of the porous layered structure shown in FIGS. 3A and 9, according to an exemplary aspect.

FIG. 12 is a schematic cross-sectional illustration of a coated porous layer with a thermal coating, according to an exemplary aspect.

FIG. 13 is a schematic cross-sectional illustration of a coated porous layer with a material coating, according to an exemplary aspect.

FIG. 14 is a schematic cross-sectional illustration of a coated porous layer with a filled material coating, according to an exemplary aspect.

FIGS. 15 and 16 are schematic cross-sectional illustrations of a coated porous layered structure with a coated porous layer shown in FIGS. 12-14, according to exemplary aspects.

FIG. 17 is a schematic manufacturing diagram for forming the coated porous layered structure shown in FIGS. 15 and 16, according to an exemplary aspect.

FIG. 18 is a flow diagram for forming the coated porous layered structure shown in FIGS. 15 and 16, according to an exemplary aspect.

The features and exemplary aspects of the aspects will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to affect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The term “about” or “substantially” or “approximately” as used herein means the value of a given quantity that can vary based on a particular technology. Based on the particular technology, the term “about” or “substantially” or “approximately” can indicate a value of a given quantity that varies within, for example, 0.1-10% of the value (e.g., ±0.1%, ±1%, ±2%, ±5%, or ±10% of the value).

The term “epitaxy” or “epitaxial” as used herein means crystalline growth of material, for example, via high temperature deposition. Epitaxy can be effected in a molecular beam epitaxy (MBE) tool in which layers are grown on a heated substrate in an ultra-high vacuum environment. Elemental sources are heated in furnaces and directed towards the substrate without carrier gases. The elemental constituents react at the substrate surface to create a deposited layer.

Epitaxy can also be performed in a vapor phase epitaxy (VPE) tool, also known as a chemical vapor deposition (CVD) tool. CVD is the formation of stable solids by decomposition of gaseous chemicals using heat, plasma, ultraviolet, or other energy sources. Silicon epitaxy can be produced by CVD using heat as the energy source to decompose gaseous chemicals. For example, silicon and dopant atoms can be brought to a single crystal surface by gaseous transport to form a doped epitaxial layer. The CVD tool can be controlled by reactor design variables and operator variables, each of which can influence the uniformity, productivity, and quality of the epitaxial layer.

Epitaxy can also be performed in a metal-organic vapor phase epitaxy (MOVPE) tool, also known as a metal-organic chemical vapor deposition (MOCVD) tool. Compound metal-organic and hydride sources flow over a heated surface using a carrier gas, for example, hydrogen. Epitaxial deposition in the MOCVD tool occurs at higher pressures than in an MBE tool. The compound constituents are cracked in the gas phase and then reacted at the surface to grow layers of desired composition.

The term “compound semiconductor material” or “Group III-V semiconductor” or “III-V semiconductor” or “III-V material” as used herein means including one or more materials from Group III of the periodic table (e.g., group 13 elements: boron (B), aluminum (Al), gallium (Ga), indium (In), thallium (Tl)) with one or more materials from Group V of the periodic table (e.g., group 15 elements: nitrogen (N), phosphorus (P), arsenic (As), antimony (Sb), bismuth (Bi)). The compounds have a 1:1 combination of Group III and Group V regardless of the number of elements from each group. Subscripts in chemical symbols of compounds refer to the proportion of that element within that group. For example, Al_{0.25}GaAs means the Group III part comprises 25% Al, and thus 75% Ga, while the Group V part comprises 100% As.

The term “Group IV semiconductor” as used herein indicates comprising one or more materials from Group IV of the periodic table (e.g., group 14 elements: carbon (C), silicon (Si), germanium (Ge), tin (Sn), lead (Pb)). An alloy can be formed from one or more Group IV elements. Subscripts in chemical symbols of the alloy refer to the proportion of that element within the alloy. For example, Si_{0.8}Ge_{0.2} means the alloy comprises 80% Si and 20% Ge.

The term “Group II-VI semiconductor” as used herein indicates comprising one or more materials from Group II of the periodic table (e.g., group 12 elements: zinc (Zn), cadmium (Cd), mercury (Hg)) with one or more materials from Group VI of the periodic table (e.g., group 16 elements: oxygen (O), sulfur(S), selenium (Se), tellurium (Te)).

The term “substrate” as used herein means a planar wafer on which subsequent layers may be deposited, formed, or grown. A substrate may be formed of a single element (e.g., Si) or a compound material (e.g., GaAs), and may be doped or undoped. In some aspects, for example, a substrate can include Si, Ge, GaAs, GaN, GaP, GaSb, InP, InSb, a Group IV semiconductor, a Group III-V semiconductor, a Group II-VI semiconductor, graphene, or silicon carbide (SiC).

A substrate may be on-axis, that is where the growth surface aligns with a crystal plane. For example, a substrate can have <100> crystal orientation. Reference herein to a substrate in a given crystal orientation also encompass a substrate which is miscut by up to about 20° towards another crystallographic direction. For example, a (100) substrate miscut towards the (111) plane.

The term “monolithic” as used herein means a layer or substrate comprising bulk (e.g., single) material throughout. Alternatively, the layer or substrate may be porous for some or all of its thickness.

The term “doping” or “doped” as used herein means that a layer or material contains a small impurity concentration of another element (dopant) which donates (donor) or extracts (acceptor) charge carriers from the parent material and therefore alters the conductivity. Charge carriers may be electrons or holes. A doped material with extra electrons is called n-type while a doped material with extra holes (fewer electrons) is called p-type.

The term “crystalline” as used herein means a material or layer with a single crystal orientation. In epitaxial growth or deposition, subsequent layers with the same or similar lattice constant follow the registry of the previous crystalline layer and therefore grow with the same crystal orientation or crystallinity. As will be understood by a person of ordinary skill in the art, crystal orientation, for example, <100> means the face of cubic crystal structure and encompasses [100], [010], and [001] orientations using the Miller indices. Similarly, for example, <0001> encompasses [0001] and [000-1], except if the material polarity is critical. Also, integer multiples of any one or more of the indices are equivalent to the unitary version of the index. For example, (222) is equivalent to (111).

The term “lattice matched” as used herein means that two crystalline layers have the same, or similar, lattice spacing such that the second layer will tend to grow isomorphically (e.g., same crystalline form) on the first layer, also known as pseudomorphic (e.g., near-lattice-matched).

The term “lattice constant” as used herein means the smallest periodicity of a crystalline lattice along a certain crystal orientation. For example, the unstrained lattice spacing of a crystalline unit cell.

The term “deposition” as used herein means the depositing of a layer on another layer or substrate. Deposition encompasses epitaxy, physical vapor deposition (PVD), electron-beam PVD (EBPVD), sputter deposition, chemical vapor deposition (CVD), plasma-enhanced CVD (PECVD), atomic layer deposition (ALD), powder bed deposition, and/or other known techniques to deposit material in a layer.

The term “lateral” or “in-plane” as used herein means parallel to the surface of the substrate and perpendicular to the growth direction.

The term “vertical” or “out-of-plane” as used herein means perpendicular to the surface of the substrate and in the growth direction.

The term “porosifying” or “porosification” as used herein means forming a porous region with a particular thickness and porosity in a layer or substrate. The porosity of a material is affected by electrolyte concentration, electrolyte current density, electrolyte current fluid velocity, anodization time, temperature, and/or material doping. Porosifying can include electrochemical (EC) etching or photoelectrochemical (PEC) etching to form one or more porous layers in a layer or substrate. For example, an electrolyte current (e.g., hydrofluoric acid (HF) at 100 mA/cm² and 20° C.) can be applied to a layer to form one or more porous layers.

The term “porous region” or “porous layer” as used herein means a layer that includes air or vacuum pores, with the porosity defined as the proportion of the area which is occupied by the pores rather than the bulk (e.g., single) material (e.g., a percentage %). The porosity can vary through the thickness of the layer. For example, the layer may be porous in one or more sublayers. The layer may include an upper portion which is porous and a lower portion that is non-porous. The porosity may be constant or variable within the porous region. Where the porosity is variable, the porosity may be linearly varied through the thickness, or may be varied according to a different function, for example, quadratic, logarithmic, or a step function. Pores in the porous layer can be microporous (e.g., less than 2 nm pore size), mesoporous (e.g., 2 nm to 50 nm pore size), nanoporous (e.g., less than 100 nm pore size), or macroporous (e.g., 50 nm to 1000 nm pore size).

Numerical values, including endpoints of ranges, can be expressed herein as approximations preceded by the term “about,” “substantially,” “approximately,” or the like. In such cases, other aspects include the particular numerical values. Regardless of whether a numerical value is expressed as an approximation, two aspects are included in this disclosure: one expressed as an approximation, and another not expressed as an approximation. It will be further understood that an endpoint of each range is significant both in relation to another endpoint, and independently of another endpoint.

Before describing aspects of the present disclosure in more detail, it is instructive to present exemplary layered structures, porosification systems, and environments in which aspects of the present disclosure may be implemented.

### Exemplary Layered Structures and Porosification Systems

As discussed above, porous semiconductors are an alternative to current incumbent RF-SOI technology that utilize trap-rich SOI substrates. Porosification can form a thick porous region with a particular thickness (e.g., greater than 10 microns) and porosity (e.g., about 35% to 65%) in a layer or substrate, and achieve high-resistivity (e.g., greater than 5,000 Ω·cm) on a standard CMOS wafer (e.g., silicon wafer). The high-resistivity porous layer (e.g., porous silicon) can suppress harmonic losses by several orders of magnitude more than trap-rich SOI. Further, the porous layer provides an epitaxy platform to regrow a defect-free, single crystal epilayer. For example, such an epilayer can be used as a device layer for RF circuit components (e.g., an RF CMOS switch).

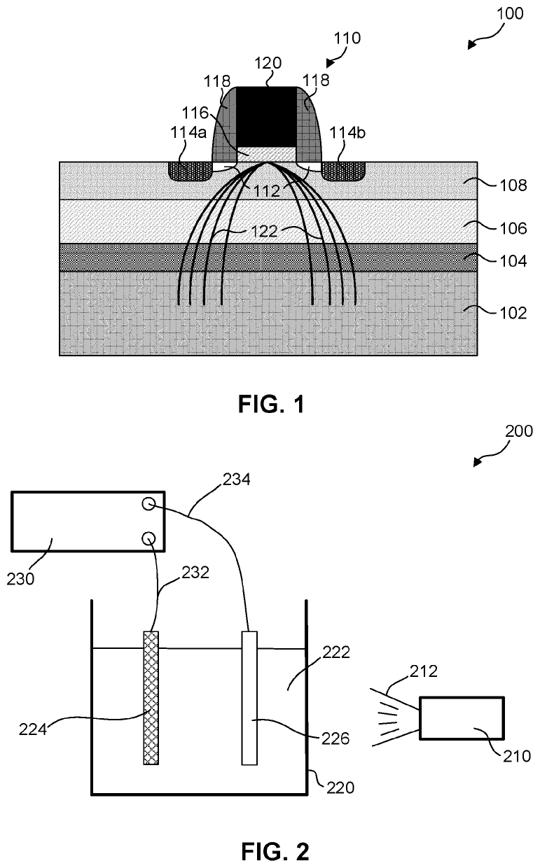

FIG. 1 illustrates trap-rich SOI layered structure 100, according to a previously known configuration. In the example shown in FIG. 1, trap-rich SOI layered structure 100 includes substrate 102 (e.g., silicon), trap-rich layer 104 (e.g., polysilicon), buried oxide (BOX) layer 106 (e.g., silicon dioxide), semiconductor layer 108 (e.g., silicon), and semiconductor device 110 (e.g., MOSFET) in semiconductor layer 108. According to such a configuration, semiconductor device 110 produces RF field lines 122 that penetrate (bleed) through trap-rich layer 104 and BOX layer 106 into substrate 102. This configuration causes significant harmonic losses, crosstalk, and parasitic surface conduction effects.

Semiconductor device 110 can include lightly doped regions 112, source/drain junctions 114a, 114b, gate oxide 116, spacers 118, and gate 120. Lightly doped regions 112 can be implanted with a dopant of a different type (e.g., n-type) than the corresponding semiconductor layer 108 (e.g., p-type). Source/drain junctions 114a, 114b can be implanted with a dopant of the same type as adjacent lightly doped regions 112, but having a higher concentration than lightly doped regions 112. Gate oxide 116 can comprise an electrical insulator, for example, silicon dioxide (SiO₂). Spacers 118 can comprise an electrical insulator, for example, silicon nitride (SiN). Gate 120 can comprise an electrical conductor, for example, polysilicon.

FIG. 2 illustrates porosification system 200, according to an exemplary aspect. Porosification system 200 can be configured to form one or more porous layers in a layer or substrate. In some aspects, porosification system 200 can utilize electrochemical (EC) etching, photoelectrochemical (PEC) etching, or a combination thereof to form one or more porous layers. Although porosification system 200 is shown in FIG. 2 as a stand-alone apparatus and/or system, aspects of this disclosure can be used with other apparatuses, systems, and/or methods.

As shown in FIG. 2, porosification system 200 can include illumination source 210, bath 220, and current source 230. In some aspects, a portion of a layer or substrate (e.g., in-plane or out-of-plane) can be exposed to an electrolyte current such that the portion is etched and a porous region remains. In some aspects, a porosity of the porous region can be controlled by adjusting electrolyte concentration, electrolyte current density, electrolyte current fluid velocity, porosification time, temperature, material doping, illumination power, and/or illumination wavelength. In some aspects, a thickness of the porous region can be controlled by adjusting a porosification (etching) time.

Illumination source 210 is configured to supplement EC etching of a layer or substrate (e.g., substrate 226) in bath 220 with PEC etching to form a porous region in the layer or substrate. PEC etching is dopant and bandgap selective and creates holes at the surface of the layer or substrate. Illumination source 210 can include a UV source (e.g., mercury lamp, arc lamp, etc.) and generate PEC illumination 212 over a portion or all of the layer or substrate. In some aspects, illumination source 210 can be a pulsed light source or include a mechanical modulator (e.g., chopper), an acousto-optical modulator (AOM), or an electro-optical modulator (EOM) to generate pulsed illumination having a particular frequency. In some aspects, illumination source 210 can have a power of about 1 mW to 10 W. In some aspects, illumination source 210 can include an optical filter to apply a particular wavelength(s) to the layer or substrate. In some aspects, illumination source 210 can be omitted for pure EC etching.

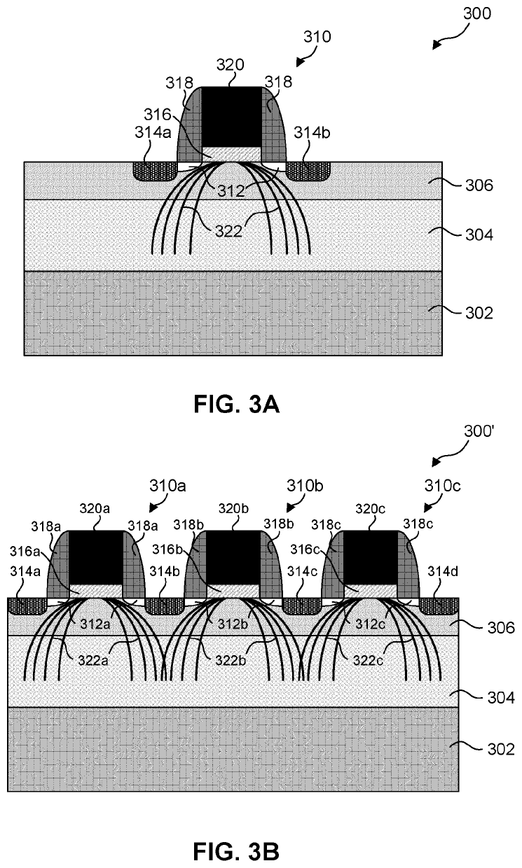

Bath 220 is configured to provide EC etching (e.g., chemical etch) of a layer or substrate (e.g., substrate 226) to form a porous region in the layer or substrate. Bath 220 can include electrolyte 222, electrode 224, and substrate 226 (e.g., substrate 302 shown in FIGS. 3A and 3B). In some aspects, electrolyte 222 can include any material (e.g., acid, alkali, oxidizer, salt, etc.) to facilitate EC etching of substrate 226. For example, electrolyte 222 can include hydrofluoric (HF) acid, buffered HF (5:2), hydrochloric (HCl) acid, hydrobromic (HBr) acid, sulfuric acid (H₂SO₄), nitric acid (HNO₃), oxalic acid (C₂H₂O₄), sodium hydroxide (NaOH), potassium hydroxide (KOH), hydrogen peroxide (H₂O₂), or any other suitable acid, alkali, salt, or oxidizer. Electrode 224 can include any suitable conductor (e.g., metal, copper (Cu), aluminum (Al), platinum (Pt), etc.). In some aspects, bath 220 can maintain a temperature of about 20° C. to about 60° C. In some aspects, substrate 226 can include substrate 302 or a portion (e.g., upper surface) of substrate 302 shown in FIGS. 3A and 3B. In some aspects, substrate 226 can be coupled to a holder such that one side of substrate 226 (e.g., frontside) is exposed to electrolyte 222 during EC etching while the opposite side of the substrate 226 (e.g., backside) is sealed and not exposed to electrolyte 222 during EC etching.

Current source 230 is configured to provide EC etching (e.g., current etch) of a layer or substrate (e.g., substrate 226) to form a porous region in the layer or substrate. Current source 230 can include cathode 232 and anode 234. When combined, current source 230 and bath 220 form an electrolyte current. In some aspects, as shown in FIG. 2, cathode 232 can be connected to electrode 224 and anode 234 can be connected to substrate 226 to complete the circuit. When current is applied, substrate 226 is etched (e.g., porosified), with or without illumination source 210, and electron flow is away from substrate 226 towards electrode 224. Electrons resonate at pore tips in substrate 226 and porosity extends through substrate 226. In some aspects, the electrolyte current density is about 1 mA/cm² to about 350 mA/cm². For example, the electrolyte current density can be about 10 mA/cm² to about 100 mA/cm². In some aspects, the lattice parameter of the starting material (e.g., substrate 226) remains relatively unchanged following the porosification process. In some aspects, a porosification rate in substrate 226 can be about 1 nm/min to about 25 μm/min. For example, the porosification rate can be about 0.1 μm/min to about 5 μm/min.

In some aspects, porosification system 200 can perform a porosification process (e.g., EC etch) on substrate 226 by exposing a portion of substrate 226 (e.g., frontside) to electrolyte 222 (e.g., buffered HF) and applying (passing) an electrolyzing current (e.g., in a range of 5 mA/cm² to 50 mA/cm²) through substrate 226 from cathode 232 and anode 234 for a specified time (e.g., for 10 seconds to 15 minutes). In some aspects, the porosification process can be carried out in a constant voltage mode (e.g., DC bias of about 5 V to about 25 V) and controlled by monitoring an etching current signal. In some aspects, the porosification process can include oxidation of substrate 226 by localized injection of holes upon application of a positive anodic bias (e.g., anode 234), and localized dissolution of such oxide layer in electrolyte 222 resulting in a porous layer (e.g., porous layer 304 shown in FIGS. 3A and 3B). In some aspects, the porosification process ends when the etching current signal drops to a base line level, indicating that all of the exposed portions of substrate 226 have been porosified and converted into a porous layer (e.g., porous layer 304 shown in FIGS. 3A and 3B).

In some aspects, substrate 226 can comprise any suitable substrate having a predetermined crystallographic orientation, including but not limited to silicon, germanium, and III-V semiconductors. In some aspects, substrate 226 can be doped prior to porosification to adjust a resistivity of substrate 226, for example, to a low-resistivity in a range of about 0.1 Ω·cm to 10 Ω·cm. In some aspects, electrolyte 222 can include a mixture of HF and deionized water, for example, having a ratio of (5:2) and surfactant (1 ml/l). In some aspects, electrolyte 222 can include a mixture of HF and an alcohol (e.g., ethanol), for example, having a ratio of (5:2).

In some aspects, porosification system 200 can form a porous layer (e.g., porous layer 304 shown in FIGS. 3A and 3B) that provides an epitaxy platform for subsequent regrowth of a defect-free, single crystal epilayer (e.g., epilayer 306 shown in FIGS. 3A and 3B). For example, porosification system 200 can form a porous layer (e.g., porous layer 304 shown in FIGS. 3A and 3B) with a low porosity (e.g., about 35%) such that the porous layer is relatively crystalline and long-range crystallinity of the porous layer is not significantly affected by the porosification process.

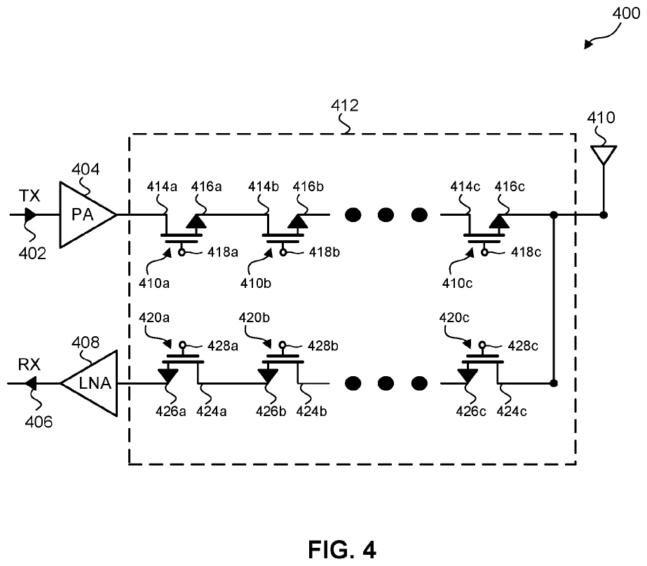

FIGS. 3A and 3B illustrate porous layered structures 300, 300′, according to exemplary aspects. Porous layered structures 300, 300′ can be configured to reduce signal leakage and suppress RF fringing fields (bleeding). In some aspects, porous layered structures 300, 300′ can be utilized in an RF device, for example, RF switch 412 shown in FIG. 4. Although porous layered structures 300, 300′ are shown in FIGS. 3A and 3B as stand-alone apparatuses and/or systems, aspects of this disclosure can be used with other apparatuses, systems, and/or methods.

As shown in FIG. 3A, porous layered structure 300 can include substrate 302 (e.g., silicon), porous layer 304 (e.g., porous silicon), epilayer 306 (e.g., single crystal silicon epilayer), and semiconductor device 310 (e.g., MOSFET) in epilayer 306. In some aspects, porous layered structure 300 with high-resistivity porous layer 304 (e.g., greater than about 5,000 Ω·cm) prevents RF field lines 322 from semiconductor device 310 from penetrating (bleeding) into substrate 302. In some aspects, porous layered structure 300 suppresses harmonic losses, reduces crosstalk, and reduces parasitic surface conduction effects.

In some aspects, substrate 302 can comprise any suitable substrate having a predetermined crystallographic orientation, including but not limited to silicon, germanium, and III-V semiconductors. In some aspects, substrate 302 can be doped prior to porosification to adjust a resistivity of substrate 302, for example, to a low-resistivity in a range of about 0.1 Ω·cm to 10 Ω·cm.

In some aspects, porous layer 304 can be a fully depleted porous layer (i.e., free of charge carriers). In some aspects, porous layer 304 can be a porous silicon layer. For example, porous layer 304 can be formed from a silicon substrate. In some aspects, porous layer 304 can have a resistivity greater than about 5,000 Ω·cm. In some aspects, porous layer 304 can have a thickness greater than about 10 microns. In some aspects, porous layer 304 can have a porosity of about 35% to 65%. In some aspects, pores in porous layer 304 can be mesoporous (e.g., 2 nm to 50 nm pore size).

In some aspects, epilayer 306 can be a defect-free, single crystal epilayer formed directly atop porous layer 304. In some aspects, epilayer 306 can comprise any suitable epilayer having a predetermined crystallographic orientation, including but not limited to silicon, germanium, and III-V semiconductors. In some aspects, epilayer 306 can have the same crystallographic orientation as substrate 302.

Semiconductor device 310 can include lightly doped regions 312, source/drain junctions 314a, 314b, gate oxide 316, spacers 318, and gate 320. Lightly doped regions 312 can be implanted with a dopant of a different type (e.g., n-type) than the corresponding epilayer 306 (e.g., p-type). Source/drain junctions 314a, 314b can be implanted with a dopant of the same type as adjacent lightly doped regions 312, but having a higher concentration than lightly doped regions 312. Gate oxide 316 can comprise an electrical insulator, for example, SiO₂. Spacers 318 can comprise an electrical insulator, for example, SiN. Gate 320 can comprise an electrical conductor, for example, polysilicon. In some aspects, semiconductor device 310 can be a transistor (e.g., MOSFET) in a CMOS device, for example, an RF switch (e.g., RF switch 412 shown in FIG. 4).

In some aspects the semiconductor device 310 can be formed directly in or on the porous layer 304 and the epilayer 306 be omitted. The semiconductor device 310 is therefore a passive device such as an inductor or filter.

The aspects of porous layered structure 300 shown in FIG. 3A, for example, and the aspects of porous layered structure 300′ shown in FIG. 3B may be similar. Similar reference numbers are used to indicate features of the aspects of porous layered structure 300 shown in FIG. 3A and the similar features of the aspects of porous layered structure 300′ shown in FIG. 3B.

As shown in FIG. 3B, porous layered structure 300′ can include a plurality of semiconductor devices 310a, 310b, 310c in epilayer 306. In some aspects, semiconductor devices 310a, 310b, 310c can be transistors, for example, MOSFETs. In some aspects, as shown in FIG. 3B, source/drain junction 314b can be shared by semiconductor devices 310a, 310b and source/drain junction 314c can be shared by semiconductor devices 310b, 310c. In some aspects, semiconductor devices 310a, 310b, 310c can be utilized in an RF device, for example, RF switch 412 shown in FIG. 4. For example, semiconductor devices 310a, 310b, 310c can generally correspond to transistors 410a, 410b, 410c (or transistors 420a, 420b, 420c) utilized in RF switch 412 shown in FIG. 4.

In some aspects the semiconductor devices 310a, 310b, 310c can be formed directly in or on the porous layer 304 and the epilayer 306 be omitted. The semiconductor devices 310a, 310b, 310c are therefore a passive device such as an inductor or filter.

FIG. 4 illustrates a circuit diagram of a portion of transceiver 400 with RF switch 412, according to an exemplary aspect. RF switch 412 can be configured to switch transceiver 400 between receive and transmit modes. In some aspects, transceiver 400 can be for a wireless communication device. Although transceiver 400 is shown in FIG. 4 as a stand-alone apparatus and/or system, aspects of this disclosure can be used with other apparatuses, systems, and/or methods.

As shown in FIG. 4, transceiver 400 can include transmit input (TX) 402, power amplifier (PA) 404, receive output (RX) 406, low-noise amplifier (LNA) 408, antenna 410, and RF switch 412. RF switch 412 is situated between PA 404 and antenna 410. PA 404 amplifies RF signals transmitted from transmit input 402. The output of PA 404 is coupled to one end of RF switch 412. Another end of RF switch 412 is coupled to antenna 410. Antenna 410 can transmit amplified RF signals. RF switch 412 is also situated between LNA 408 and antenna 410. Antenna 410 also receives RF signals. Antenna 410 is coupled to one end of RF switch 412. Another end of RF switch 412 is coupled to the input of LNA 408. LNA 408 amplifies RF signals received from RF switch 412. Receive output 406 receives amplified RF signals from LNA 408. In some aspects, RF switch 412 can employ stacked transistors.

RF switch 412 can include two stacks of transistors. The first stack includes transistors 410a, 410b, and 410c. Each transistor 410a, 410b, 410c has a corresponding drain 414a, 414b, 414c, source 416a, 416b, 416c, and gate 418a, 418b, 418c. The second stack includes transistors 420a, 420b, and 420c. Each transistor 420a, 420b, 420c has a corresponding drain 424a, 424b, 424c, source 426a, 426b, 426c, and gate 428a, 428b, 428c. When transistors 410a, 410b, and 410c are in OFF states, and transistors 420a, 420b, and 420c are in ON states, transceiver 400 is in receive mode. When transistors 410a, 410b, and 410c are in ON states, and transistors 420a, 420b, and 420c are in OFF states, transceiver 400 is in transmit mode. In some aspects, RF switch 412 can switch transceiver 400 between two transmit modes corresponding to different frequencies, or between two receive modes corresponding to different frequencies. In some aspects, RF switch 412 can be utilized in a semiconductor structure that reduces signal leakage.

### Exemplary Uncoated Porous Layered Structures

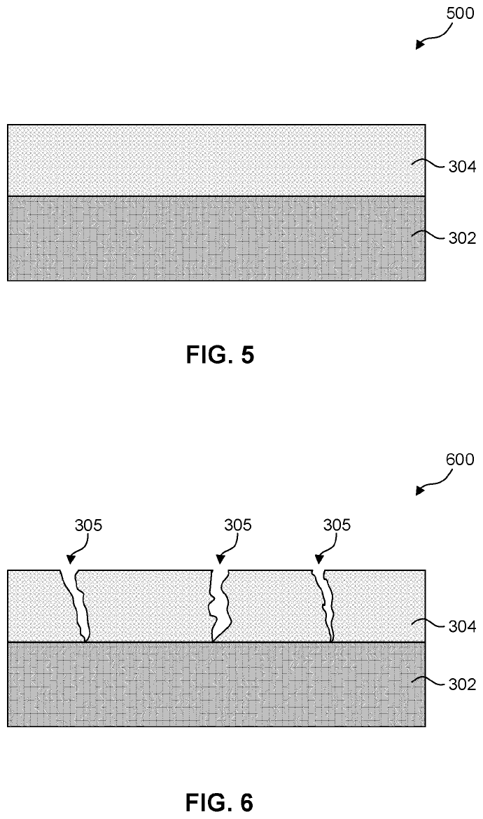

FIG. 5 illustrates uncoated porous layered structure 500 prior to high temperature processing, according to an exemplary aspect. As shown in FIG. 5, uncoated layered structure 500 can include porous layer 304 over substrate 302. In some aspects, porous layer 304 can have a thickness of at least 5 μm. For example, porous layer 304 can have a thickness of between about 5 μm and about 10 μm. In some aspects, porous layer 304 can have a thickness of at least 10 μm. For example, porous layer 304 can have a thickness of between about 10 μm and about 50 μm.

FIG. 6 illustrates uncoated porous layered structure 600 after high temperature processing, according to an exemplary aspect. As shown in FIG. 6, uncoated porous layered structure 600 includes porous layer 304 with cracks 305 throughout due to high temperature processing. In some aspects, cracks 305 are created due to thermal instability in porous layer 304. For example, cracks 305 can be created by migration and/or reorganization of semiconductor atoms (e.g., silicon) in porous layer 304.

In some aspects, high temperature processing can include a temperature of at least 400° C. For example, high temperature processing can include a temperature between about 400° C. and about 800° C. In some aspects, high temperature processing can include a temperature of at least 800° C. For example, high temperature processing can include a temperature between about 800° C. and about 1200° C. In some aspects, high temperature processing can include epitaxial processing. For example, epitaxial processing can include growing an epitaxial layer (e.g., epilayer 306 shown in FIG. 3A) over porous layer 304 at a temperature of at least 400° C.

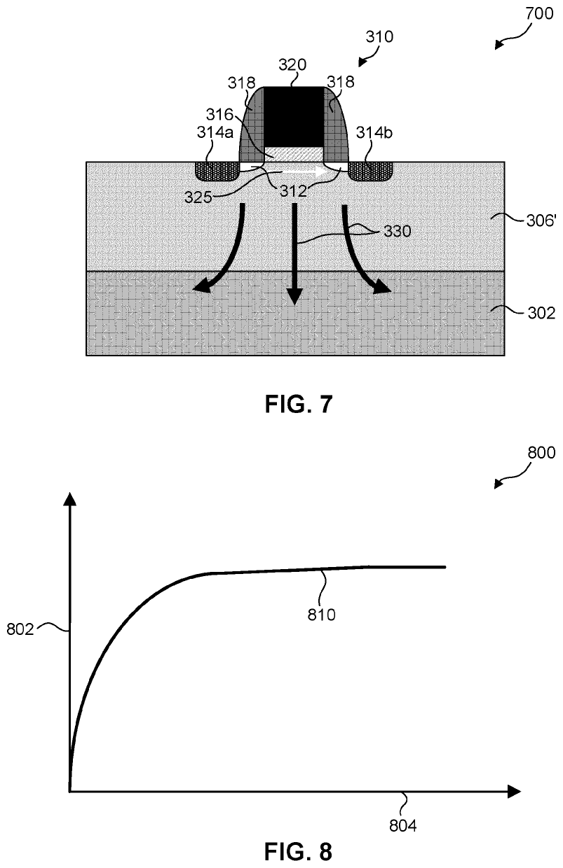

The aspects of porous layered structure 300 shown in FIG. 3A, for example, and the aspects of layered structure 700 shown in FIG. 7 may be similar. Similar reference numbers are used to indicate features of the aspects of porous layered structure 300 shown in FIG. 3A and the similar features of the aspects of layered structure shown in FIG. 7.

FIG. 7 illustrates layered structure 700 with limited self-heating, according to an exemplary aspect. As shown in FIG. 7, layered structure 700 can include epilayer 306′ over substrate 302 that forms an active channel 325 of semiconductor device 310. During device operation, an electrical current flows between source/drain junctions 314a, 314b, generating a significant amount of heat in the active channel 325. Self-heating occurs when heat generated by the active channel 325 cannot be effectively dissipated, resulting in the active channel 325 becoming more resistive thereby degrading (lowering) an output current of semiconductor device 310. In some aspects, epilayer 306′ can include a high thermally conductive material, for example, silicon having a thermal conductivity of about 149 W/m·K. In some aspects, layered structure 700 can be configured to dissipate heat and reduce self-heating of semiconductor device 310. For example, as shown in FIG. 7, epilayer 306′ (e.g., silicon) can effectively dissipate heat 330 generated by active channel 325 such that self-heating effects are reduced.

FIG. 8 shows a plot 800 of device output current (I) 802 as a function of applied voltage (V) 804 for layered structure 700 shown in FIG. 7, according to an exemplary aspect. As shown in FIG. 8, the I-V curve 810 has limited self-heating and device output current (I) 802 is relatively constant in a saturation region as applied voltage (V) 804 is increased due to the high thermal conductivity properties (e.g., thermal conductivity of about 149 W/m·K) of epilayer 306′ of layered structure 700.

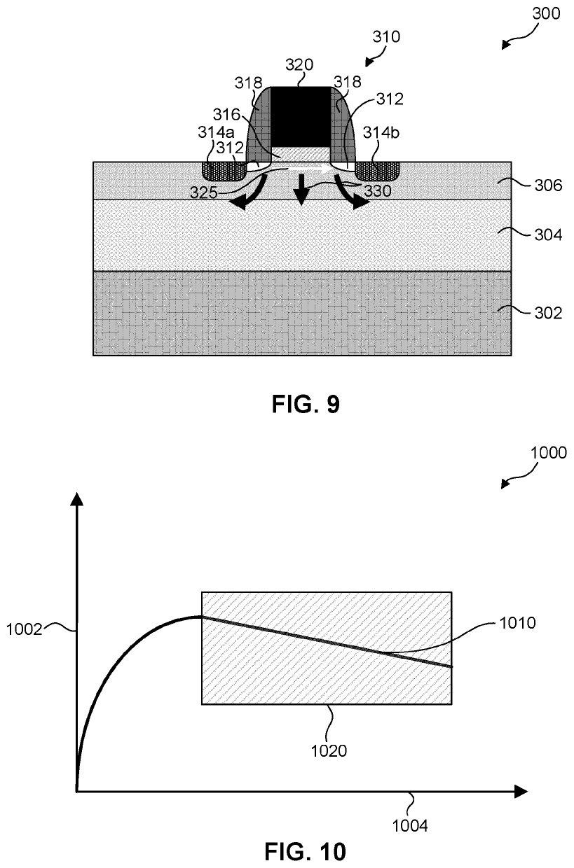

FIG. 9 illustrates porous layered structure 300 shown in FIG. 3A with self-heating, according to an exemplary aspect. As shown in FIG. 9, porous layered structure 300 can include epilayer 306 over porous layer 304 that forms an active channel 325 of semiconductor device 310. In some aspects, porous layer 304 can have a thickness of at least 5 μm. For example, porous layer 304 can have a thickness of between about 5 μm and about 20 μm. In some aspects, porous layer 304 can include a low thermally conductive material, for example, porous silicon having a thermal conductivity of about 3 W/m·K. In some aspects, porous layered structure 300 can have reduced heat dissipation and device performance degradation due to self-heating of semiconductor device 310. For example, as shown in FIG. 9, porous layer 304 (e.g., porous silicon) cannot effectively dissipate heat 330 generated by active channel 325 resulting in self-heating effects and degradation of semiconductor device 310 performance.

FIG. 10 shows a plot 1000 of device output current (I) 1002 as a function of applied voltage (V) 1004 for porous layered structure 300 shown in FIGS. 3A and 9, according to an exemplary aspect. As shown in FIG. 10, the I-V curve 1010 has self-heating and device output current (I) 802 is degraded (lowered) in a self-heating region 1020 as applied voltage (V) 1004 is increased due to the low thermal conductivity properties (e.g., thermal conductivity of about 3 W/m·K) of porous layer 304 of porous layered structure 300.

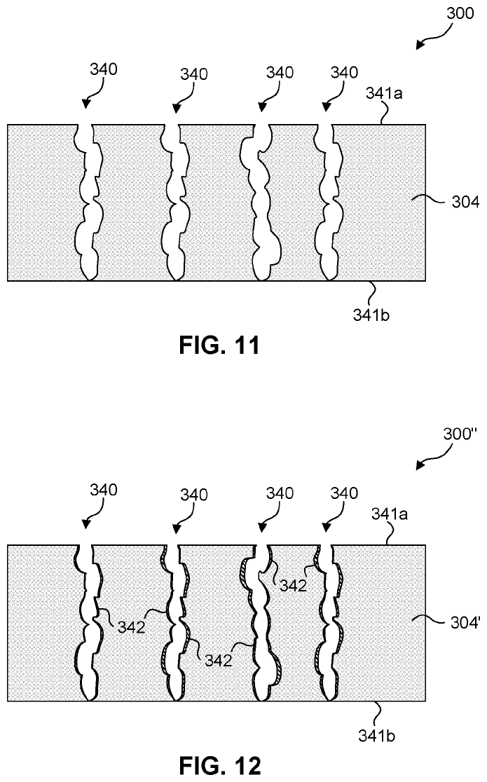

FIG. 11 illustrates porous layer 304 of porous layered structure 300 shown in FIGS. 3A and 9, according to an exemplary aspect. As shown in FIG. 11, porous layer 304 has a frontside 341a and a backside 341b and includes porous walls 340. In some aspects, as shown in FIG. 11, porous walls 340 can extend through porous layer 304 from the frontside 341a to the backside 341b. In some aspects, porous walls 340 can be microporous, for example, having a diameter of less than about 2 nm. In some aspects, porous walls 340 can be mesoporous, for example, having a diameter between about 2 nm to about 50 nm. In some aspects, porous walls 340 can be nanoporous, for example, having a diameter of less than about 100 nm. In some aspects, porous walls 340 can be macroporous, for example, having a diameter between about 50 nm to about 1000 nm.

### Exemplary Coated Porous Layers

As discussed above, when a thick porous layer (e.g., thickness of at least 5 μm) undergoes high temperature processing (e.g., greater than 400° C.), cracking and flaking in the porous layer can occur. For example, as shown in FIG. 6, cracks 305 can form in porous layer 304 which degrades the quality of porous layer 304 and subsequent epitaxial growth (e.g., epilayer 306) on porous layer 304. Further, semiconductor atoms (e.g., silicon) in the porous layer can migrate and reorganize during high temperature processing causing thermal instability in the porous layer, for example, as shown in FIG. 6 by uncoated porous layered structure 600. In addition, porous silicon has a low thermal conductivity (e.g., about 3 W/m·K), which can lead to self-heating in an active device channel and degraded output current. For example, as shown in FIGS. 9 and 10, self-heating can occur in active channel 325 of semiconductor device 310 due to poor heat dissipation 330 in porous layer 304, resulting in self-heating region 1020 in I-V curve 1010.

Aspects of coated porous layer apparatuses, systems, and methods as discussed below can simultaneously improve thermal stability of a porous layer, reduce cracking and flaking during high temperature processing of the porous layer, maintain high resistivity of the porous layer (e.g., greater than 5,000 Ω·cm), increase thermal conductivity of the porous layer (e.g., greater than about 5 W/m·K), and reduce self-heating in a semiconductor device in a porous layered structure.

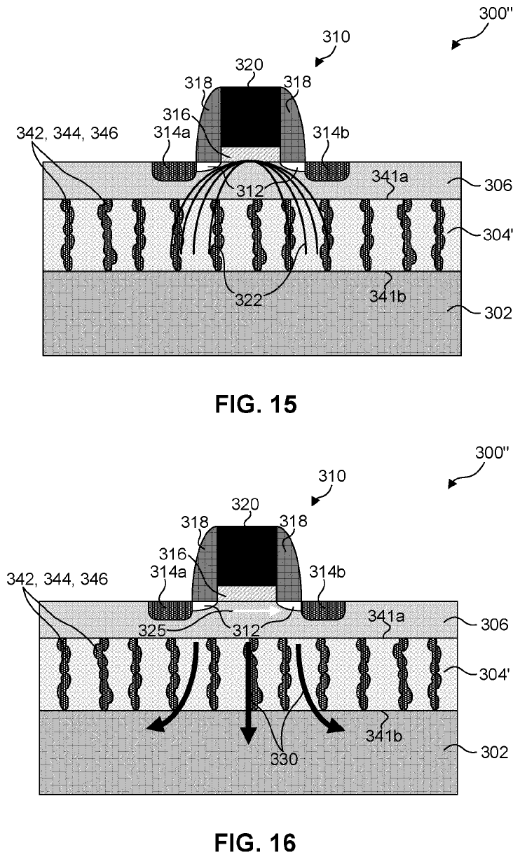

FIGS. 12-14 illustrate coated porous layers 304′ for coated porous layered structure 300″ shown in FIGS. 15 and 16, according to exemplary aspects. Coated porous layers 304′ can be configured to improve thermal stability of porous layer 304. Coated porous layers 304′ can be further configured to maintain a high resistivity (e.g., greater than 5,000 Ω·cm) of porous layer 304. Coated porous layers 304′ can be further configured to increase a thermal conductivity (e.g., greater than about 5 W/m·K) of porous layer 304. Coated porous layers 304′ can be further configured to reduce self-heating in semiconductor device 310. In some aspects, coated porous layers 304′ can be utilized in a porous layered structure, for example, porous layered structure 300″ shown in FIGS. 15 and 16. Although coated porous layers 304′ are shown in FIGS. 12-14 as stand-alone apparatuses and/or systems, aspects of this disclosure can be used with other apparatuses, systems, and/or methods, for example, porous layered structure 300″, manufacturing diagram 1700, and/or flow diagram 1800.

The aspects of porous layer 304 shown in FIG. 11, for example, and the aspects of coated porous layers 304′ shown in FIGS. 12-14 may be similar. Similar reference numbers are used to indicate features of the aspects of porous layer 304 shown in FIG. 11 and the similar features of the aspects of coated porous layers 304′ shown in FIGS. 12-14.

As shown in FIG. 12, coated porous layer 304′ can include thermal coating 342 coupled to porous walls 340. Thermal coating 342 can be configured to improve thermal stability of porous layer 304. Thermal coating 342 can be further configured to maintain a high resistivity (e.g., greater than 5,000 Ω·cm) of porous layer 304. In some aspects, thermal coating 342 can include a thermal oxide. For example, thermal coating 342 can include silicon dioxide. In some aspects, thermal coating 342 can be formed by a low temperature oxidation bake (anneal). For example, porous layer 304 can be heated to a temperature of at least 200° C. in an oxygen environment (e.g., air) to form thermal coating 342 (e.g., silicon dioxide) within coated porous layer 304′. In some aspects, thermal coating 342 can have a thickness less than 5 nm. For example, thermal coating 342 can have a thickness of about 2 nm. In some aspects, thermal coating 342 can have a thickness between about 5 nm to about 50 nm. For example, thermal coating 342 can have a thickness of about 20 nm. In some aspects, thermal coating 342 can completely cover porous walls 340.

In some aspects, thermal coating 342 can be formed along porous walls 340. For example, as shown in FIG. 12, thermal coating 342 can extend continuously along porous walls 340 from frontside 341a to backside 341b of coated porous layer 304′. In some aspects, thermal coating 342 can be electrically insulating. For example, thermal coating 342 can include an electrically insulating oxide (e.g., silicon dioxide). In some aspects, thermal coating 342 can be configured to decrease (e.g., block) migration of atoms in coated porous layer 304′ thereby increasing a thermal stability of coated porous layer 304′ at high temperatures. For example, thermal coating 342 (e.g., silicon oxide) can decrease migration of atoms (e.g., silicon) at temperatures greater than about 850° C.

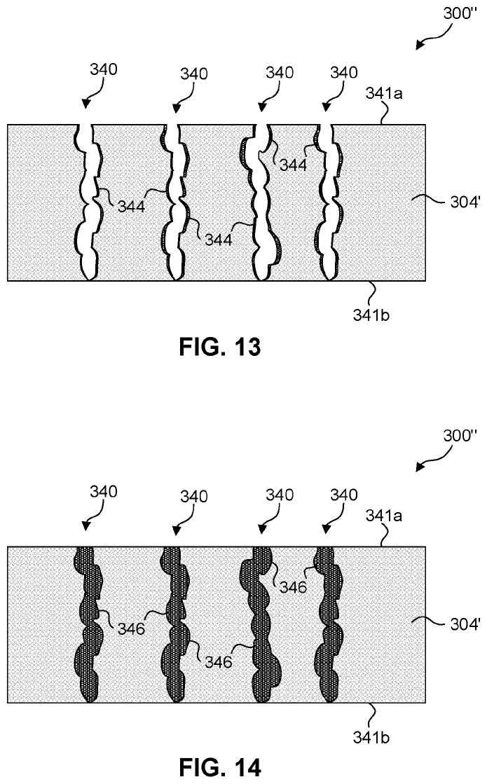

As shown in FIG. 13, coated porous layer 304′ can include material coating 344 coupled to porous walls 340. Material coating 344 can be configured to improve thermal stability of porous layer 304. Material coating 344 can be further configured to maintain a high resistivity (e.g., greater than 5,000 Ω·cm) of porous layer 304. Material coating 344 can be further configured to increase a thermal conductivity (e.g., greater than about 5 W/m·K) of porous layer 304. Material coating 344 can be further configured to reduce self-heating in semiconductor device 310.

In some aspects, material coating 344 can have a thermal conductivity greater than a thermal conductivity of porous silicon (e.g., about 0.1-5 W/m·K). In some aspects, material coating 344 can have a thermal conductivity of at least 10 W/m·K. In some aspects, material coating 344 can have a thermal conductivity of at least 30 W/m·K. In some aspects, material coating 344 can have a thermal conductivity of at least 50 W/m·K.

In some aspects, material coating 344 can have a high thermal conductivity. In some aspects, material coating 344 can have a thermal conductivity of at least 100 W/m·K. For example, material coating 344 can include silicon (Si) having a thermal conductivity of about 149 W/m·K, silicon carbide (SiC) having a thermal conductivity of about 270 W/m·K, or a combination thereof. In some aspects, material coating 344 can have a thermal conductivity of at least 300 W/m·K. For example, material coating 344 can include aluminum nitride (AlN) having a thermal conductivity of about 321 W/m·K, beryllium oxide (BeO) having a thermal conductivity of about 330 W/m·K, or a combination thereof. In some aspects, material coating 344 can have a thermal conductivity of at least 500 W/m·K. For example, material coating 344 can include boron nitride (BN) (e.g., hexagonal BN) having a thermal conductivity of about 600 W/m·K, an allotrope of carbon (C) (e.g., diamond) having a thermal conductivity between about 500 W/m·K to about 2,000 W/m·K, or a combination thereof.

In some aspects, material coating 344 can include germanium (Ge), Si, SiC, AlN, BeO, BN, C, or a combination thereof. For example, material coating 344 can include AlN having a thermal conductivity of about 321 W/m·K. In some aspects, material coating 344 can include an allotrope of C. For example, material coating 344 can include diamond, graphite, graphene, fullerenes, fullerite, carbon nanotubes, amorphous carbon, nanocarbons, glassy carbon, carbon nanofoam, or a combination thereof.

In some aspects, material coating 344 can increase a total thermal conductivity of coated porous layer 304′ to at least 10 W/m·K. Heat transfer thermal resistance paths (e.g., heat dissipation 330 shown in FIG. 16) of material coating 344 and porous layer 304 through a thickness of coated porous layer 304′ are in parallel, and therefore thermal conductivities are in series and based on area weighting. Total thermal conductivity (K) through a thickness of coated porous layer 304′ can be approximated as

$$K = {k}_{potous} ( 1 - p ) + {k}_{M} pf$$

where kₚₒᵣₒᵤₛ is a thermal conductivity of porous layer 304, k_{M} is a thermal conductivity of material coating 344, p is a porosity of coated porous layer 304′, and f is a filling factor based on a ratio of a thickness of material coating 344 coupled to porous walls 340 and a diameter of porous walls 340. For example, for porous layer 304 being porous silicon having kₚₒᵣₒᵤₛ≈3 W/m·K, material coating 344 being AlN having k_{M}≈321 W/m·K, a porosity of 35% (p=0.35), and a filling factor of 20% (f=0.2) (e.g., a diameter of porous walls 340 being about 20 nm and a thickness of material coating 344 being about 2 nm), a total thermal conductivity of coated porous layer 304′ is about 24.4 W/m·K. For example, for porous layer 304 being porous silicon having kₚₒᵣₒᵤₛ≈3 W/m·K, material coating 344 being Ge having k_{M}≈60.2 W/m·K, a porosity of 50% (p=0.5), and a filling factor of 100% (f=1.0) (e.g., material coating 344 completely covers porous walls 340), a total thermal conductivity of coated porous layer 304′ is about 31.6 W/m·K.

In some aspects, material coating 344 can increase a total thermal conductivity of coated porous layer 304′ to at least 100 W/m·K. For example, for porous layer 304 being porous silicon having kₚₒᵣₒᵤₛ≈3 W/m·K, material coating 344 being AlN having k_{M}≈321 W/m·K, a porosity of 65% (p=0.65), and a filling factor of 60% (f=0.6) (e.g., a diameter of porous walls 340 being about 10 nm and a thickness of material coating 344 being about 3 nm), a total thermal conductivity of coated porous layer 304′ is about 126 W/m·K. For example, for porous layer 304 being porous silicon having kₚₒᵣₒᵤₛ≈3 W/m·K, material coating 344 being BN having k_{M}≈600 W/m·K, a porosity of 70% (p=0.7), and a filling factor of 80% (f=0.8) (e.g., a diameter of porous walls 340 being about 20 nm and a thickness of material coating 344 being about 8 nm), a total thermal conductivity of coated porous layer 304′ is about 337 W/m·K. For example, for porous layer 304 being porous silicon having kₚₒᵣₒᵤₛ≈3 W/m·K, material coating 344 being diamond having k_{M}≈2,000 W/m·K, a porosity of 25% (p=0.25), and a filling factor of 100% (f=1.0) (e.g., material coating 344 completely covers porous walls 340), a total thermal conductivity of coated porous layer 304′ is about 502 W/m·K.

In some aspects, material coating 344 can be formed by deposition, including but not limited to, PVD, EBPVD, sputtering, CVD, PECVD, ALD, spin-coating, dip-coating, spray-coating, and/or any other thin-film deposition techniques. For example, material coating 344 can be formed by ALD. In some aspects, material coating 344 can have a thickness less than 5 nm. For example, material coating 344 can have a thickness of about 2 nm. In some aspects, material coating 344 can have a thickness between about 5 nm to about 100 nm. For example, material coating 344 can have a thickness of about 30 nm. In some aspects, material coating 344 can completely cover porous walls 340. For example, as shown in FIG. 14, filled material coating 346 can completely cover porous walls 340. In some aspects, prior to deposition of material coating 344, porous walls 340 of porous layer 304 can be exposed to an acid solution to remove any native oxide and/or contaminants on porous walls 340. For example, porous layer 304 can undergo an HF dip and subsequently flushed with deionized (DI) water.

In some aspects, after deposition of material coating 344, coated porous layer 304′ can undergo a touch polish to remove an upper surface layer (e.g., frontside 341a) and expose the underlying porous structure (e.g., porous walls 340) prior to subsequent epitaxial growth. For example, frontside 341a of coated porous layer 304′ can be polished by a chemical mechanical polishing (CMP) or planarization process. In some aspects, after deposition of material coating 344, coated porous layer 304′ can undergo a plasma surface etch to remove an upper surface layer (e.g., frontside 341a) and expose the underlying porous structure (e.g., porous walls 340) prior to subsequent epitaxial growth. For example, frontside 341a of coated porous layer 304′ can be etched by a plasma etcher.

In some aspects, material coating 344 can be formed along porous walls 340. For example, as shown in FIG. 13, material coating 344 can extend continuously along porous walls 340 from frontside 341a to backside 341b of coated porous layer 304′. In some aspects, material coating 344 can be electrically insulating. For example, material coating 344 can include Ge, Si, SiC, AlN, BeO, BN, C, or a combination thereof. In some aspects, material coating 344 can be configured to decrease (e.g., block) migration of atoms in coated porous layer 304′ thereby increasing a thermal stability of coated porous layer 304′ at high temperatures. For example, material coating 344 (e.g., AlN) can decrease migration of atoms (e.g., silicon) at temperatures greater than about 850° C.

In some aspects, material coating 344 can be configured to maintain a high resistivity of porous layer 304 (e.g., greater than about 5,000 Ω·cm) thereby decreasing harmonic losses in a semiconductor device. For example, as shown in FIG. 15, coated porous layer 304′ can suppress RF field lines 322 from semiconductor device 310 from penetrating (bleeding) into substrate 302. In some aspects, material coating 344 can be configured to increase a total thermal conductivity of coated porous layer 304′ thereby decreasing self-heating effects in an active device channel of a semiconductor device. For example, as shown in FIG. 16, coated porous layer 304′ can effectively dissipate heat 330 from active channel 325 of semiconductor device 310.

The aspects of material coating 344 shown in FIG. 13, for example, and the aspects of filled material coating 346 shown in FIG. 14 may be similar. Similar reference numbers are used to indicate features of the aspects of material coating 344 shown in FIG. 13 and the similar features of the aspects of filled material coating 346 shown in FIG. 14.

As shown in FIG. 14, coated porous layer 304′ can include filled material coating 346 coupled to porous walls 340. Filled material coating 346 completely covers porous walls 340. In some aspects, filled material coating 346 can be deposited or grown along porous walls 340 and a thickness of filled material coating 346 can be increased until a diameter of porous walls 340 is completely filled (e.g., filling factor of 100%).

In some aspects, filled material coating 346 can increase a total thermal conductivity of coated porous layer 304′ to at least 10 W/m·K. For example, for porous layer 304 being porous silicon having kₚₒᵣₒᵤₛ≈3 W/m·K, filled material coating 346 being Ge having k_{M}≈60.2 W/m·K, and a porosity of 30% (p=0.3), a total thermal conductivity of coated porous layer 304′ is about 20.2 W/m·K. For example, for porous layer 304 being porous silicon having kₚₒᵣₒᵤₛ≈3 W/m·K, filled material coating 346 being Si having k_{M}≈149 W/m·K, and a porosity of 40% (p=0.4), a total thermal conductivity of coated porous layer 304′ is about 61.4 W/m·K.

In some aspects, filled material coating 346 can increase a total thermal conductivity of coated porous layer 304′ to at least 100 W/m·K. For example, for porous layer 304 being porous silicon having kₚₒᵣₒᵤₛ≈3 W/m·K, filled material coating 346 being AlN having k_{M}≈321 W/m·K, and a porosity of 50% (p=0.5), a total thermal conductivity of coated porous layer 304′ is about 162 W/m·K. For example, for porous layer 304 being porous silicon having kₚₒᵣₒᵤₛ≈3 W/m·K, filled material coating 346 being BN having k_{M}≈600 W/m·K, and a porosity of 30% (p=0.3), a total thermal conductivity of coated porous layer 304′ is about 182 W/m·K.

### Exemplary Coated Porous Layered Structure

FIGS. 15 and 16 illustrate coated porous layered structure 300″ with coated porous layer 304′ shown in FIGS. 12-14, according to exemplary aspects. Coated porous layered structure 300″ can be configured to decrease harmonic losses in semiconductor device 310. Coated porous layered structure 300″ can be further configured to reduce self-heating in semiconductor device 310. Although coated porous layered structure 300″ is shown in FIGS. 15 and 16 as a stand-alone apparatus and/or system, aspects of this disclosure can be used with other apparatuses, systems, and/or methods, for example, coated porous layer 304′, manufacturing diagram 1700, and/or flow diagram 1800.

The aspects of porous layered structure 300 shown in FIGS. 3A and 9, for example, and the aspects of coated porous layered structure 300″ shown in FIGS. 15 and 16 may be similar. Similar reference numbers are used to indicate features of the aspects of porous layered structure 300 shown in FIGS. 3A and 9 and the similar features of the aspects of coated porous layered structure 300″ shown in FIGS. 15 and 16.

As shown in FIGS. 15 and 16, coated porous layered structure 300″ can include coated porous layer 304′ with thermal coating 342, material coating 344, or filled material coating 346. In some aspects, coated porous layer 304′ can have a high resistivity (e.g., greater than about 5,000 Ω·cm) thereby decreasing harmonic losses in a semiconductor device. For example, as shown in FIG. 15, coated porous layer 304′ can suppress RF field lines 322 from semiconductor device 310 from penetrating (bleeding) into substrate 302. In some aspects, coated porous layer 304′ can have a resistivity equal to or greater than a resistivity of porous layer 304. In some aspects, coated porous layer 304′ can have a high thermal conductivity (e.g., at least about 10 W/m·K) thereby decreasing self-heating effects in an active device channel of a semiconductor device. For example, as shown in FIG. 16, coated porous layer 304′ can effectively dissipate heat 330 from active channel 325 of semiconductor device 310. In some aspects, coated porous layer 304′ can have a thermal conductivity greater than a thermal conductivity of porous layer 304. For example, coated porous layer 304′ can have a thermal conductivity of at least about 10 W/m·K, at least about 30 W/m·K, at least about 50 W/m·K, at least about 100 W/m·K, at least about 300 W/m·K, or at least about 500 W/m·K.

### Exemplary Manufacturing Diagram

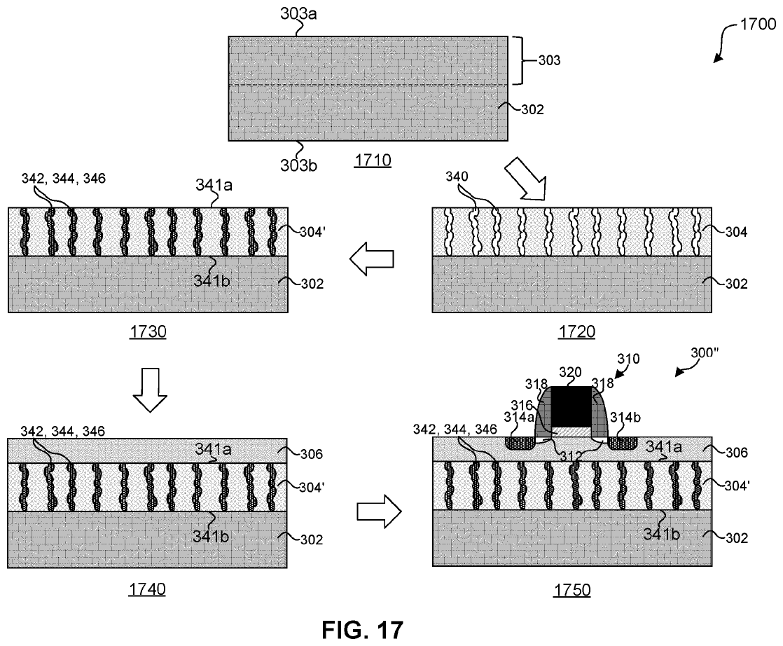

FIG. 17 illustrates manufacturing diagram 1700 for forming coated porous layered structure 300″, according to an exemplary aspect. It is to be appreciated that not all steps in FIG. 17 are needed to perform the disclosure provided herein. Further, some of the steps can be performed simultaneously, sequentially, and/or in a different order than shown in FIG. 17. Manufacturing diagram 1700 shall be described with reference for FIGS. 11-16. However, manufacturing diagram 1700 is not limited to those example aspects.

As shown in FIG. 17, manufacturing diagram 1700 is configured to form coated porous layered structure 300″ shown in FIGS. 15 and 16. In step 1710, a substrate 302 having a frontside 303a and a backside 303b is selected. In some aspects, substrate 302 can include any suitable substrate having a predetermined crystallographic orientation, including but not limited to silicon, germanium, and III-V semiconductors.

In step 1720, a portion 303 of substrate 302 is porosified from frontside 303a towards backside 303b to form porous layer 304 with porous walls 340. In some aspects, manufacturing diagram 1700 can further include exposing porous walls 340 of porous layer 304 to an acid solution (e.g., HF) after step 1720 but prior to step 1730.

In step 1730, coated porous layer 304′ is formed by forming thermal coating 342, material coating 344, or filled material coating 346 in porous walls 340 of porous layer 304. In some aspects, for example, as shown in FIG. 12, coated porous layer 304′ can be formed by thermally oxidizing porous layer 304 to form thermal coating 342 within porous walls 340. In some aspects, for example, as shown in FIG. 13, coated porous layer 304′ can be formed by depositing material coating 344 within porous walls 340. In some aspects, for example, as shown in FIG. 14, coated porous layer 304′ can be formed by depositing filled material coating 346 completely within porous walls 340. In some aspects, manufacturing diagram 1700 can further include annealing coated porous layer 304′ after step 1730 but prior to step 1740. For example, coated porous layer 304′ can be annealed at a temperature between about 300° C. to about 500° C.

In some aspects, after step 1730 but prior to step 1740, coated porous layer 304′ can undergo a touch polish to remove an upper surface layer (e.g., frontside 341a) and expose the underlying porous structure (e.g., porous walls 340) prior to subsequent epitaxial growth in step 1740. For example, frontside 341a of coated porous layer 304′ can be polished by a CMP or planarization process. In some aspects, after step 1730 but prior to step 1740, coated porous layer 304′ can undergo a plasma surface etch to remove an upper surface layer (e.g., frontside 341a) and expose the underlying porous structure (e.g., porous walls 340) prior to subsequent epitaxial growth in step 1740. For example, frontside 341a of coated porous layer 304′ can be etched by a plasma etcher.

In step 1740, an epilayer 306 is grown over coated porous layer 304′ (e.g., on frontside 341a). In some aspects, epilayer 306 can include any suitable epilayer having a predetermined crystallographic orientation, including but not limited to silicon, germanium, and III-V semiconductors. In some aspects, epilayer 306 can be a defect-free, single crystal epilayer formed directly atop coated porous layer 304′.

In step 1750, a semiconductor device 310 is formed in epilayer 306 to form coated porous layered structure 300″. In some aspects, semiconductor device 310 can be a transistor (e.g., MOSFET) in a CMOS device, for example, an RF switch (e.g., RF switch 412 shown in FIG. 4). In some aspects, coated porous layered structure 300″ can omit semiconductor device 310 in epilayer 306, for example, as shown in step 1740 of FIG. 17. In some aspects, coated porous layered structure 300″ can omit epilayer 306 over coated porous layer 304′, for example, as shown in step 1730 of FIG. 17.

### Exemplary Flow Diagram

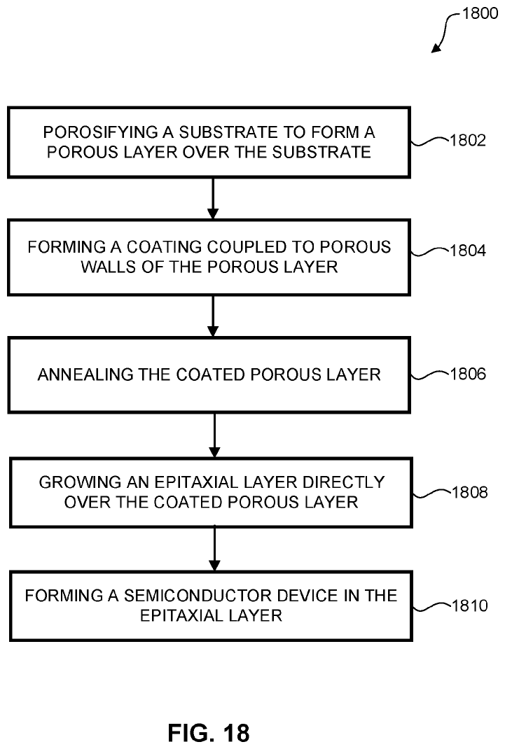

FIG. 18 illustrate flow diagram 1800 to describe the process of forming coated porous layered structure 300″, according to an exemplary aspect. It is to be appreciated that not all steps in FIG. 18 are needed to perform the disclosure provided herein. Further, some of the steps can be performed simultaneously, sequentially, and/or in a different order than shown in FIG. 18. Flow diagram 1800 shall be described with reference to FIGS. 11-17. However, flow diagram 1800 is not limited to those example aspects.

As shown in FIG. 18, flow diagram 1800 describes the process to form coated porous layered structure 300″ shown in FIGS. 15 and 16. In step 1802, as shown in the example of FIG. 17, a portion 303 of substrate 302 is porosified from frontside 303a towards backside 303b to form porous layer 304 with porous walls 340. In some aspects, flow diagram 1800 can further include exposing porous walls 340 of porous layer 304 to an acid solution (e.g., HF) after porosifying substrate 302 to form porous layer 304. In step 1804, as shown in the example of FIG. 17, coated porous layer 304′ is formed by forming thermal coating 342, material coating 344, or filled material coating 346 coupled to porous walls 340 of porous layer 304. In step 1806, coated porous layer 304′ is annealed. In some aspects, flow diagram 1800 can omit step 1806. In step 1808, as shown in the example of FIG. 17, an epilayer 306 is grown over coated porous layer 304′ (e.g., on frontside 341a). In step 1810, as shown in the example of FIG. 17, a semiconductor device 310 is formed in epilayer 306 to form coated porous layered structure 300″.

In some aspects, after step 1804 but prior to step 1808, coated porous layer 304′ can undergo a touch polish to remove an upper surface layer (e.g., frontside 341a) and expose the underlying porous structure (e.g., porous walls 340) prior to subsequent epitaxial growth in step 1808. For example, frontside 341a of coated porous layer 304′ can be polished by a CMP or planarization process. In some aspects, after step 1804 but prior to step 1808, coated porous layer 304′ can undergo a plasma surface etch to remove an upper surface layer (e.g., frontside 341a) and expose the underlying porous structure (e.g., porous walls 340) prior to subsequent epitaxial growth in step 1808. For example, frontside 341a of coated porous layer 304′ can be etched by a plasma etcher. In some aspects, coated porous layer 304′ can undergo a touch polish or a plasma surface etch after step 1804 but prior to step 1806. In some aspects, coated porous layer 304′ can undergo a touch polish or a plasma surface etch after step 1806 but prior to step 1808.

It is to be understood that the phraseology or terminology herein is for the purpose of description and not of limitation, such that the terminology or phraseology of the present specification is to be interpreted by those skilled in relevant art(s) in light of the teachings herein.

The following examples are illustrative, but not limiting, of the aspects of this disclosure. Other suitable modifications and adaptations of the variety of conditions and parameters normally encountered in the field, and which would be apparent to those skilled in the relevant art(s), are within the spirit and scope of the disclosure.

While specific aspects have been described above, it will be appreciated that the aspects can be practiced otherwise than as described. The description is not intended to limit the scope of the claims.

The aspects have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects will so fully reveal the general nature of the aspects that others can, by applying knowledge within the skill of the art, readily modify and/or adapt for various applications such specific aspects, without undue experimentation, without departing from the general concept of the aspects. Therefore, such adaptations and modifications are intended to be within the meaning and range of equivalents of the disclosed aspects, based on the teaching and guidance presented herein.

The breadth and scope of the aspects should not be limited by any of the above-described exemplary aspects, but should be defined only in accordance with the following claims and their equivalents.

1. A layered structure comprising:
a substrate;
a porous layer over the substrate, the porous layer having a higher resistivity than the substrate; and
a coating coupled to porous walls of the porous layer, wherein the coating has a thermal conductivity of at least 30 W/m·K.

2. The layered structure of claim 1, wherein the coating has a thermal conductivity of at least 50 W/m·K or at least 100 W/m·K.

3. The layered structure of claim 1, wherein the coating comprises germanium (Ge), silicon carbide (SiC), aluminum nitride (AlN), beryllium oxide (BeO), boron nitride (BN), or carbon (C), or wherein the coating comprises an allotrope of carbon including diamond, graphite, graphene, fullerenes, fullerite, carbon nanotubes, amorphous carbon, nanocarbons, glassy carbon, carbon nanofoam, or a combination thereof.

4. The layered structure of claim 1, wherein the coating is electrically insulating.

5. The layered structure of claim 1, wherein the coating extends continuously along the porous walls from a frontside of the porous layer to a backside of the porous layer or the coating completely covers the porous walls.

6. The layered structure of claim 1, wherein the coating has a thickness less than 5 nm.

7. The layered structure of claim 1, wherein the porous layer has a thickness of at least 2 μm.

8. The layered structure of claim 1, further comprising a device on the porous layer.

9. The layered structure of claim 1, further comprising an epitaxial layer grown directly over the porous layer.

10. The layered structure of claim 9, further comprising a semiconductor device in the epitaxial layer.

11. A method comprising:
forming a porous layer over a substrate, the porous layer having a higher resistivity than the substrate; and
forming a coating coupled to porous walls of the porous layer, wherein the coating has a thermal conductivity of at least 30 W/m·K.

12. The method of claim 11, wherein forming the coating comprises depositing the coating on the porous walls by atomic layer deposition (ALD).

13. The method of claim 11, wherein forming the coating comprises forming the coating continuously along the porous walls from a frontside of the porous layer to a backside of the porous layer or completely covering the porous walls.

14. The method of claim 11, further comprising exposing the porous walls to an acid solution prior to or after forming the coating.

15. The method of claim 11, further comprising annealing the porous layer.

16. The method of claim 11, wherein forming the porous layer comprises porosifying an upper portion of the substrate.

17. The method of claim 11, further comprising forming a passive device on the porous layer and/or growing an epitaxial layer directly over the porous layer.
